(19) United States
(12) Patent Application Publication
(10) Pub. No.: US 2024/0249038 A1
(43) Pub. Date: Jul. 25, 2024

(54) APPARATUS FOR PREDICTING ABSORBANCE SPECTRUM OF MIXED DYE BASED ON CCM REFLECTANCE AND METHOD USING THE SAME

(71) Applicant: ELECTRONICS AND TELECOMMUNICATIONS RESEARCH INSTITUTE, Daejeon (KR)

(72) Inventors: Ji Yong HWANG, Daejeon (KR); Hyun Woo OH, Daejeon (KR)

(21) Appl. No.: 18/397,025

(22) Filed: Dec. 27, 2023

(30) Foreign Application Priority Data
Dec. 29, 2022 (KR) 10-2022-0189783

(51) Int. Cl. G06F 30/20

(52) U.S. Cl. CPC G06F 30/20

(57) ABSTRACT

An apparatus for predicting an absorbance spectrum of a mixed dye based on CCM reflectance data. The apparatus includes: an input module receiving input of a customer order for dyeing; and a processor reproducing an absorbance spectrum through conversion of reflectance data in a QTX file of the customer order, wherein the processor generates absorbance spectra and predicted colors through conversion of reflectance data of single-color dyes in a dyeing factory; implements a predicted absorbance spectrum of a mixed dye produced according to a recommended single-color dye mixing ratio corresponding to CCM values of the customer order; compares the predicted absorbance spectrum of the mixed dye with the absorbance spectrum according to the customer order; and complements or corrects the recommended single-color dye mixing ratio to match the predicted absorbance spectrum of the mixed dye to the absorbance spectrum according to the customer order.

### CROSS-REFERENCE TO RELATED APPLICATION

This application claims priority to and the benefit of Korean Patent Application No. 10-2022-0189783, filed on Dec. 29, 2022, the disclosure of which is incorporated herein by reference in its entirety.

### BACKGROUND

### 1. Field of the Invention

The present invention relates to an apparatus for predicting an absorbance spectrum of a mixed dye based on CCM reflectance data and a method using the same and, more particularly, to an apparatus for predicting an absorbance spectrum of a mixed dye based on CCM reflectance data, which can correct a single-color dye mixing ratio for reproduction of a color ordered by a customer in a dyeing process, and a method using the same.

### 2. Description of Related Art

In general, a dyeing process in the textile industry is a process that reproduces a requested color under a requested light source (for example, A/10, U35, D65, etc.) and on a requested fabric according to a customer order (request).

A conventional dyeing process corresponding to the customer order is as follows.

The customer order is given to a dyer (for example, a dyeing factory) or a dyeing site in the form of a QTX file in which colorimetric values are stored along with information about a specific standard light (that is, light source conditions), a colorimeter model of a CCM (computer color matching) system, and software (SW) for driving the colorimeter (that is, a file storing CCM colorimetric values), a color chip allowing CCM colorimetry, a fabric swatch sample, or the like.

In CCM colorimetry, a requested color under a specific standard light source according to a customer order is expressed in X, Y, and Z values in a color space coordinate system and is stored in a QTX file.

A CCM colorimetry system constructs basic data by dyeing a raw fabric with single-color dyes stored and used at a dyeing site (for example, a dyeing factory) at varying concentrations, followed by CCM colorimetry.

In the conventional dyeing process, based on colorimetric values measured on a QTX file, a swatch sample, and the like provided by a customer using a CCM system, a skilled worker selects single-color dyes from on-site basic data input in advance and repeats the task of adjusting the mixing ratio of the selected single-color dyes according to their know-how to match a resulting color to a requested color of the customer order. The mixing ratio of the selected single-color dyes may be simulated by calculating a deviation of X, Y, and Z values of the basic data from X, Y, and Z values in the QTX file and, among multiple single-color dye mixing ratios recommended from the simulation results, a single-color dye mixing ratio considered most appropriate according to the know-how of the worker is selected and subjected to a beaker test (B/T) (a first stage) at the laboratory level.

After the beaker test (B/T), a colorimetric value of a dyed fabric is measured using the CCM system to be compared with a CCM colorimetric value of the customer order, and the single-color dye mixing ratio is corrected to reduce a color difference, followed by another beaker test (B/T).

After finding a single-color dye mixing ratio that meets the CCM colorimetric value of the customer order (that is, after succeeding in reproduction of the color requested by the customer) in the beaker test (B/T) stage, scale-up to a dyeing factory for mass production is conducted and experimental dyeing (a second stage) is carried out on a 100 kg dyeing machine.

This step repeats a procedure in which the colorimetric value of the fabric is measured once more using the CCM system after experimental dyeing to be compared to the colorimetric value of the customer order, followed by correction of the single-color dye mixing ratio to reduce a color difference.

From a subsequent process step to on-site dyeing (a continuous dyeing process, a third stage), color difference correction through comparison with the CCM colorimetric value of the customer order is repeatedly performed. In addition, a color difference from the CCM colorimetric value of the customer order is also checked during quality testing of final dyeing products after post-processing.

The key point in such a dyeing process is that, in the beaker test (B/T) stage performed at a dyeing site that has received a customer order, confirmation of data (that is, CCM colorimetric value) by CCM colorimetry on a QTX file, a color chip, and the like contained in the customer order, making a selection from single-color dyes stored and used at the dyeing site, and repeated simulation to find a single-color dye mixing ratio enabling reproduction of the color requested by the customer rely on a skilled worker with decades of know-how in this area.

In the conventional dyeing process, although a worker with decades of know-how in a dyeing factory can roughly identify single-color dyes to be mixed among dyes used in the dyeing factory, as described above, it is difficult to know whether the identified dyes are the best dye candidates capable of realizing an optimal dye combination. In addition, when there is no skilled worker in the dyeing factory and a worker with relatively little experience performs the task, a resulting single-color dye mixing ratio is further unreliable.

For this reason, repeated runs of the beaker test (B/T) are required to reproduce a desired color for one final dyed product, which is time-consuming and costly.

A background technique of the present invention is disclosed in Korean Patent Registration No. 10-0257320 (registered on Feb. 29, 2000).

This background technique provides a task management apparatus that allows a computerized color matching task to be consistently managed until the task is completed when a user selects specific input values from lists of quantities of an object to be colored, light source conditions, dyes to be used, dyeing methods, and the like. However, the background technique has a problem in that a user selecting the input values for the task management apparatus has to be a skilled worker with many years of know-how.

### SUMMARY OF THE INVENTION

Embodiments of the present invention have been conceived to solve such a problem in the art and it is an aspect of the present invention to provide an apparatus for predicting an absorbance spectrum of a mixed dye based on CCM reflectance data, which can correct a single-color dye mixing ratio for reproduction of a color ordered by a customer using absorbance spectra of dyes based on CCM reflectance data in a dyeing process, and a method using the same.

In accordance with one aspect of the present invention, an apparatus for predicting an absorbance spectrum of a mixed dye based on CCM reflectance data includes: an input module receiving input of a customer order for dyeing; and a processor reproducing an absorbance spectrum through conversion of reflectance data in a QTX file of the customer order, wherein the processor generates absorbance spectra and predicted colors through conversion of reflectance data of single-color dyes in a dyeing factory; implements a predicted absorbance spectrum of a mixed dye produced according to a recommended single-color dye mixing ratio corresponding to CCM values of the customer order; compares the predicted absorbance spectrum of the mixed dye with the absorbance spectrum according to the customer order; and complements or corrects the recommended single-color dye mixing ratio to match the predicted absorbance spectrum of the mixed dye to the absorbance spectrum according to the customer order.

The processor may identify X, Y, and Z values in the QTX file of the customer order using a CCM system, may select single-color dyes stored in the dyeing factory for use in actual production; and may output the recommended single-color dye mixing ratio by calculating a deviation of X, Y, and Z values of basic data from the identified X, Y, and Z values and performing simulation.

The processor may convert reflectance (% R or R) data into absorbance (A) data using a mathematical formula containing correction factors A=−log(R) and A=1/log(% R)+α.

The processor may collect absorbance data converted from reflectance data to construct reflectance-based absorbance data of the single-color dyes used in the dyeing factory.

The processor may perform regression analysis to generate a mathematical model for each single-color dye through combination of functions predicting absorbance as a function of wavelength depending on single-color dyes, a wavelength range, and dye concentrations set by a worker in the dyeing factory and may implement concentration-dependent absorbance spectra of the single-color dyes through the mathematical model.

The processor may perform quantitative analysis to identify change in color coordinate X, Y, and Z values in a QTX file corresponding to CCM colorimetry results, as measured under a standard light source set by the worker, depending on change in concentration of each single-color dye and may combine functions fₓ, f_{y}, and f_{z} capable of predicting the color coordinate X, Y, and Z values depending on an arbitrary concentration of each single-color dye through regression analysis of quantitative analysis results to generate a mathematical model capable of predicting a color of a dyeing product corresponding to the standard light source and the concentration of the single-color dyes set by the worker in the dyeing factory.

The processor may implement concentration-dependent absorbance spectra of single-color dyes of various colors using basic absorbance data of single-color dyes stored in the dyeing factory for use in actual production, as calculated using a mathematical model, and may predict the absorbance spectrum of the mixed dye produced by mixing the single-color dyes.

The processor may compare the predicted absorbance spectrum of the mixed dye with the absorbance spectrum converted from the reflectance data of the customer order, may complement or correct a single-color dye mixing ratio recommended by a CCM system through adjustment of the concentration of each single-color dye or through replacement with another single-color dye having a similar color to increase matching between the predicted absorbance spectrum of the mixed dye and the absorbance spectrum converted from the reflectance data of the customer order, and may output a predicted color and a predicted color intensity (K/S) corresponding to the complemented or corrected single-color dye mixing ratio.

In accordance with another aspect of the present invention, a method of predicting an absorbance spectrum of a mixed dye based on CCM reflectance data includes: reproducing, by a processor, an absorbance spectrum through conversion of reflectance data in a QTX file of a customer order; implementing, by the processor, absorbance spectra and predicted colors through conversion of reflectance data of single-color dyes in a dyeing factory; generating, by the processor, a predicted absorbance spectrum of a mixed dye produced according to a recommended single-color dye mixing ratio corresponding to CCM values of the customer order; comparing, by the processor, the predicted absorbance spectrum of the mixed dye with the absorbance spectrum converted from the reflectance data of customer order; and complementing or correcting, by the processor, the recommended single-color dye mixing ratio to match the predicted absorbance spectrum of the mixed dye to the absorbance spectrum converted from the reflectance data of the customer order.

In order to recommend the single-color dye mixing ratio, the processor may identify X, Y, and Z values in the QTX file of the customer order using a CCM system, may select single-color dyes stored at the dyeing factory for use in actual production, and may output the recommended single-color dye mixing ratio by calculating a deviation of X, Y, and Z values of basic data from the identified X, Y, and Z values and performing simulation.

In the step of reproducing an absorbance spectrum through conversion of reflectance data in a QTX file of a customer order, the processor may convert reflectance (% R or R) data to absorbance (A) data using a mathematical formula containing correction factors A=−log(R) and A=1/log(% R)+α.

The processor may perform regression analysis to generate a mathematical model for each single-color dye through combination of functions predicting absorbance as a function of wavelength depending on single-color dyes, a wavelength range, and dye concentrations set by a worker in the dyeing factory and may implement concentration-dependent absorbance spectra of the single-color dyes through the mathematical model.

In order to generate the mathematical model for each single-color dye, the processor may perform quantitative analysis to identify change in color coordinate X, Y, and Z values in a QTX file corresponding to CCM colorimetry results, as measured under a standard light source set by the worker, depending on change in concentration of each single-color dye, may combine functions fₓ, f_{y}, and f_{z} capable of predicting the color coordinate X, Y, and Z values depending on an arbitrary concentration of each single-color dye through regression analysis of quantitative analysis results, and may generate a mathematical model capable of predicting a color of a dyeing product corresponding to the standard light source and the concentration of the single-color dyes set by the worker in the dyeing factory.

In the step of generating a predicted absorbance spectrum of a mixed dye, the processor may implement concentration-dependent absorbance spectra of single-color dyes of various colors using basic absorbance data of single-color dyes stored in the dyeing factory for use in actual production, as calculated using a mathematical model, and may predict the absorbance spectrum of the mixed dye produced by mixing the single-color dyes.

After generating the predicted absorbance spectrum of the mixed dye and the absorbance spectrum converted from the reflectance data of the customer order, the processor may compare the predicted absorbance spectrum of the mixed dye with the absorbance spectrum converted from the reflectance data of the customer order, may complement or correct a single-color dye mixing ratio recommended by a CCM system through adjustment of the concentration of each single-color dye or through replacement with another single-color dye having a similar color to increase matching between the predicted absorbance spectrum of the mixed dye and the absorbance spectrum converted from the reflectance data of the customer order, and may output a predicted color and a predicted color intensity (K/S) corresponding to the complemented or corrected single-color dye mixing ratio.

In accordance with a further aspect of the present invention, a method of predicting an absorbance spectrum of a mixed dye based on CCM reflectance data includes: converting, by a processor, reflectance data in a QTX file of a customer order into absorbance data and reproducing an absorbance spectrum based on the absorbance data; converting, by the processor, reflectance data of single-color dyes in a dyeing factory into absorbance data and generating absorbance spectra of the single-color dyes based on the absorbance data using a specified mathematical model; generating, by the processor, a predicted absorbance spectrum of a mixed dye produced according to a recommended single-color dye mixing ratio corresponding to CCM values of the customer order based on the absorbance spectra of the single-color dyes; and comparing, by the processor, the absorbance spectrum converted from the reflectance data of the customer order with the predicted absorbance spectrum of the mixed dye and complementing or correcting the recommended single-color dye mixing ratio to match the predicted absorbance spectrum of the mixed dye to the absorbance spectrum converted from the reflectance data of the customer order.

The processor may perform regression analysis to generate a mathematical model for each single-color dye through combination of functions predicting absorbance as a function of wavelength depending on single-color dyes, a wavelength range, and dye concentrations set by a worker in the dyeing factory and may implement concentration-dependent absorbance spectra of the single-color dyes through the mathematical model.

In order to generate the mathematical model for each single-color dye, the processor may perform quantitative analysis to identify change in color coordinate X, Y, and Z values in a QTX file corresponding to CCM colorimetry results, as measured under a standard light source set by the worker, depending on change in concentration of each single-color dye, combines functions fₓ, f_{y}, and f_{z} capable of predicting the color coordinate X, Y, and Z values depending on an arbitrary concentration of each single-color dye through regression analysis of quantitative analysis results, and may generate a mathematical model capable of predicting a color of a dyeing product corresponding to the standard light source and the concentration of the single-color dyes set by the worker in the dyeing factory.

In the step of generating a predicted absorbance spectrum of a mixed dye, the processor may implement concentration-dependent absorbance spectra of single-color dyes of various colors using basic absorbance data of single-color dyes stored in the dyeing factory for use in actual production, as calculated using a mathematical model, and may predict the absorbance spectrum of the mixed dye produced by mixing the single-color dyes.

After generating the predicted absorbance spectrum of the mixed dye and the absorbance spectrum converted from the reflectance data of the customer order, the processor may compare the predicted absorbance spectrum of the mixed dye with the absorbance spectrum converted from the reflectance data of the customer order, may complement or correct a single-color dye mixing ratio recommended by a CCM system through adjustment of the concentration of each single-color dye or through replacement with another single-color dye having a similar color to increase matching between the predicted absorbance spectrum of the mixed dye and the absorbance spectrum converted from the reflectance data of the customer order, and may output a predicted color and a predicted color intensity (K/S) corresponding to the complemented or corrected single-color dye mixing ratio.

The apparatus and method according to the present invention can correct a single-color dye mixing ratio for reproduction of a color ordered by a customer using absorbance spectra of dyes based on CCM reflectance data.

The apparatus and method according to the present invention makes it easier to select a single-color dye mixing ratio using absorbance spectra of dyes based on CCM reflectance data.

The apparatus and method according to the present invention can reduce trial and error in reducing a difference between color of a mixed dye and colorimetric values specified in a customer order, thereby reducing the time, labor, and cost associated therewith.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a schematic diagram of an apparatus for predicting an absorbance spectrum of a mixed dye based on CCM reflectance data according to one embodiment of the present invention.

FIG. 2 illustrates a QTX file containing CCM colorimetric values according to one embodiment of the present invention.

FIG. 3 is a diagram illustrating a method of converting reflectance data in a QTX file output after colorimetry into absorbance data according to one embodiment of the present invention.

FIG. 4 is a diagram illustrating a method of implementing an arbitrary concentration-dependent absorbance spectrum of each single-color dye in the visible region through a mathematical model based on absorbance (A) data converted from reflectance (% R or R) data according to one embodiment of the present invention.

FIG. 5 is a diagram illustrating a method of predicting a color depending on the concentration of a single-color dye according to one embodiment of the present invention.

FIG. 6 is a diagram illustrating implementation of absorbance spectra of single-color dyes based on CCM reflectance data and color prediction based thereon shown in FIG. 4 and FIG. 5.

FIG. 7 is a diagram illustrating implementation of absorbance spectra of single-color dyes based on CCM reflectance data and a visible absorbance spectrum of a mixed dye produced according to a specific single-color dye mixing ratio.

FIG. 8 is a diagram illustrating a method of comparing an absorbance spectrum converted from CCM reflectance data of a customer order with an absorbance spectrum of a mixed dye based on reflectance data generated at the dyeing site.

### DETAILED DESCRIPTION OF EXEMPLARY EMBODIMENTS

Hereinafter, embodiments of the present invention will be described with reference to the accompanying drawings. It should be noted that the drawings are not to precise scale and may be exaggerated in thickness of lines or size of components for descriptive convenience and clarity only. In addition, the terms used herein are defined by taking functions of the present invention into account and can be changed according to user or operator custom or intention. Therefore, definition of the terms should be made according to the overall disclosure set forth herein.

The present invention relates to an apparatus for predicting an absorbance spectrum of a mixed dye based on CCM reflectance data using a mathematical model, which is used in a dyeing process including a laboratory-level beaker test (B/T) (a first stage), experimental dyeing (a second stage), and on-site dyeing (a third stage) for reproduction of a color (that is, CCM colorimetric values) according to a customer order, can reduce trial and error associated with the beaker test (B/T) and CCM colorimetry steps repeated to reduce a difference between the color of a dyeing product and the color (that is, CCM colorimetric values) according to the customer order, and can make it easier for a relatively inexperienced worker to perform the task of selecting a single-color dye mixing ratio for reproduction of the color (that is, CCM colorimetric values) according to the customer order, which typically relies on know-how of a skilled worker.

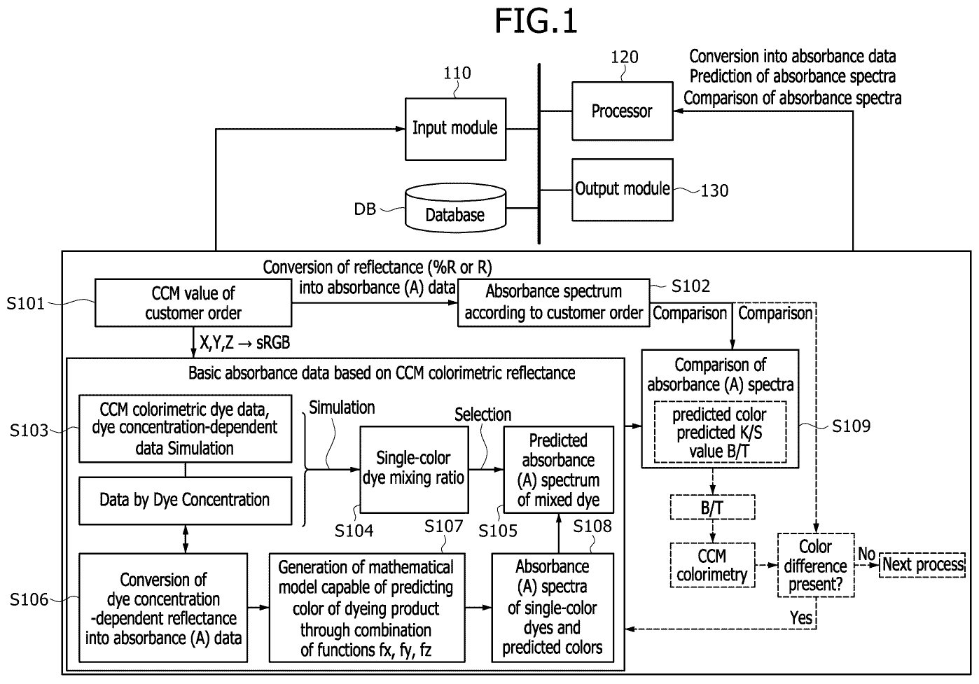

FIG. 1 is a schematic diagram of an apparatus for predicting an absorbance spectrum of a mixed dye based on reflectance data by CCM according to one embodiment of the present invention.

Referring to FIG. 1, an apparatus for predicting an absorbance spectrum of a mixed dye based on reflectance data by CCM according to this embodiment includes an input module 110, a processor 120, an output module 130, and a database (DB).

The input module 110 receives input of a customer order (for example, fabric texture, thread count, fabric composition, RGB color value, etc.). Here, the customer order may be input in the form of a QTX file.

The input module 110 may be, for example, an interface for input of data (information), such as a keyboard, a touchscreen, a USB port, and the like. In some embodiments, the input module 110 may receive input of data via communication connection.

The processor 120 may perform conversion of reflectance data into absorbance data, prediction of absorbance spectra, and comparison of absorbance spectra to select a single-color dye mixing ratio enabling reproduction of a color (that is, CCM colorimetric values) according to the customer order.

The processor 120 may be connected to a memory, wherein the memory may store a variety of information required for operation of the processor 120. The memory may also store a variety of information produced by the processor 120 during operation. The memory may include a read-only memory (ROM), a random-access memory (RAM), a flash memory, a memory card, a storage medium, and/or other storage devices.

In addition, the processor 120 may implement a multi-layer perceptron (MLP) artificial intelligence (AI) model.

The output module 130 outputs results of conversion of reflectance data into absorbance data, prediction of absorbance spectra, and comparison of absorbance spectra performed by the processor 120 through an output device (for example, a monitor).

The database (DB) may store data of dyes used at a dyeing site (or a dyeing factory) and data processed by the processor 120 (for example, results of conversion of reflectance data into absorbance data, prediction of absorbance spectra, and comparison of absorbance spectra).

Next, details of the operation of the processor 120 will be described with reference to FIG. 1.

Referring to FIG. 1, the processor 120 converts reflectance data of single-color dyes stored and used at a dyeing site (for example, a dyeing factory) (that is, reflectance data in QTX files corresponding to CCM colorimetry results for the single-color dyes as a function of concentration) into absorbance (A) data through a specified mathematical formula (that is, a mathematical formula containing a correction factor) and constructs basic absorbance data using a mathematical model generated by quantitative analysis and regression analysis of the concentration-dependent absorbance (A) data of the single-color dyes (S103 to S108).

In addition, when a customer order is given to the dyeing site, the processor 120 converts reflectance data in a QTX file contained in the customer order (that is, a QTX file corresponding to reflectance measurement results, CCM colorimetry results for a color chip, a swatch sample, and the like) into absorbance data through a mathematical formula (that is, a mathematical formula containing a correction factor) (S101) and reproduces a visible absorbance (A) spectrum according to the customer order (S102).

In addition, the processor 120 identifies X, Y, and Z values in the QTX file of the customer order using a CCM system, selects single-color dyes stored at the dyeing site for use in actual production, and outputs recommended single-color dye mixing ratios by calculating a deviation of X, Y, and Z values of the basic data from the identified X, Y, and Z values and performing simulation (S103 to S104).

In addition, the processor 120 outputs the absorbance (A) data set as the basic data (that is, absorbance values converted from concentration-dependent reflectance values of the single-color dyes) (S106), absorbance spectra (that is, concentration-dependent absorbance spectra of the single-color dyes calculated through a mathematical model), and predicted colors based thereon (S107 to S108).

In addition, the processor 120 outputs a predicted color and a predicted color intensity (K/S) through comparison (S109) of an absorbance (A) spectrum of a mixed dye produced according to the recommended single-color dye mixing ratio (that is, a predicted absorbance spectrum of the mixed dye) (S105) with an absorbance (A) spectrum converted from the reflectance data in the QTX file of the customer order (that is, the absorbance spectrum according to the customer order) (S102).

Here, the processor 120 may complement or correct the recommended single-color dye mixing ratio to visually match the absorbance spectrum of the mixed dye (that is, the predicted absorbance spectrum of the mixed dye) (S105) to the absorbance (A) spectrum according to the customer order (S102).

In this way, reliance on the know-how of skilled workers for this task can be further reduced, making it possible for workers with relatively little experience in the task to easily cope with the task, and a color difference from the color requested by a customer can be further reduced in a dyeing process including a beaker test (B/T) (a first stage), experimental dyeing (a second stage), and on-site dyeing (a third stage), thereby reducing trial and error in a conventional dyeing process requiring repeated runs and thus reducing the time, labor, and cost associated therewith.

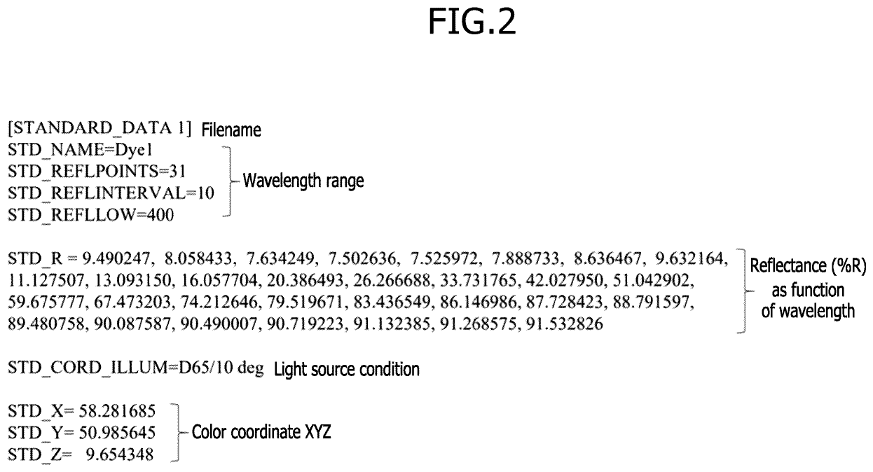

FIG. 2 illustrates a QTX file containing CCM colorimetric values according to one embodiment of the present invention.

While contents of the QTX file may slightly vary depending on the type of CCM colorimeter, the items shown in FIG. 2 (for example, filename, wavelength range, wavelength-dependent reflectance, light source condition, and color coordinate X, Y, and Z) are common to QTX files and are also included in QTX files contained in customer orders or generated by dye manufacturers or dyeing factories.

The filename of the QTX file is labeled with dye name and dye concentration input by a worker.

For example, the filename of the QTX file may be labeled “Dye1 (1.0%)”.

The wavelength range set in the QTX file may be arbitrarily set by workers at a related company and the dyeing site, and is typically the visible wavelength range of 360 nm to 700 nm.

The wavelength-dependent reflectance set in the QTX file is expressed in percentage (% R) and is converted into absorbance data through a mathematical formula containing a correction factor to generate a mathematical model for reproduction of an absorbance spectrum.

The light source condition set in the QTX file is a factor to be considered since different light sources produce different reflectance results. However, certain CCM colorimeters do not have an indication of a light source, which is always included in an order from a new customer.

X, Y, and Z values in the QTX file may be converted into sRGB values through a specific matrix to display a corresponding color on a monitor. Through this, a deviation of X, Y, and Z values for a given single-color dye mixing ratio is simulated.

Through consideration of the contents of the QTX file, conversion of reflectance data into absorbance data, reproduction of an absorbance spectrum through a mathematical model, and comparison with of an absorbance spectrum according to the customer order can be performed.

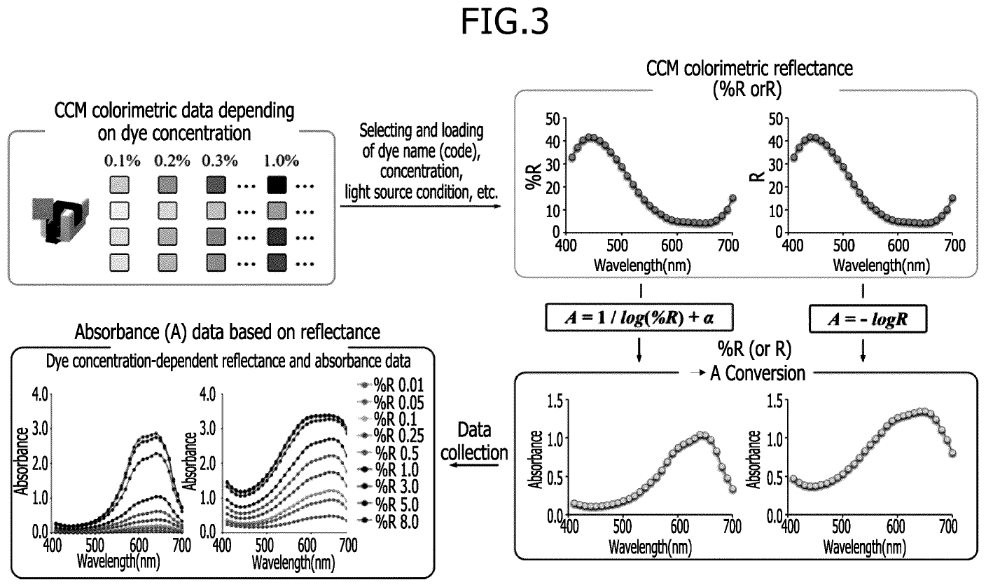

FIG. 3 is a diagram illustrating a method of converting reflectance data in a QTX file output after colorimetry into absorbance data according to one embodiment of the present invention.

A visible reflectance spectrum is reproduced by selecting dye name (dye code), dye concentration, light source condition, and the like from QTX files into which single-color dyes stored at the dyeing site for use in actual production are classified by concentration.

Since transmittance can be almost ignored in measurement of reflectance using a CCM colorimeter, the reflectance (% R or R) data may be converted into absorbance (A) data using a mathematical formula containing correction factors A=−log(R) and A=1/log(% R)+α.

Here, the absorbance (A) spectrum converted from the reflectance data (% R or R) is confirmed to have high similarity in shape to experimental absorbance data measured with a UV-Vis spectrophotometer when normalized and compared thereto.

Accordingly, collection of absorbance (A) data converted from reflectance (% R or R) data makes it possible to construct reflectance-based absorbance (A) data for single-color dyes used at the dyeing site.

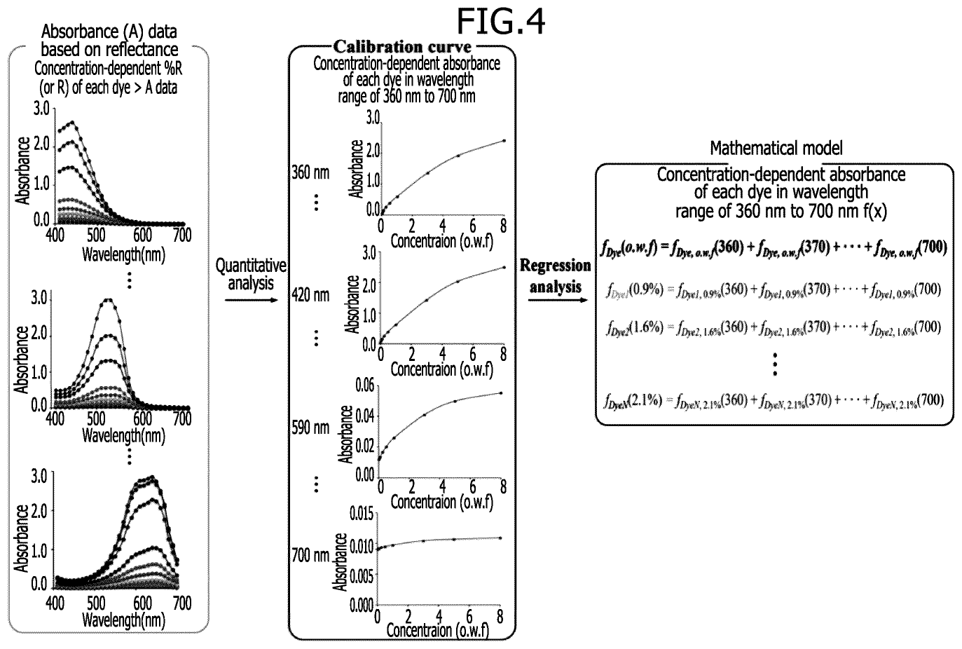

FIG. 4 is a diagram illustrating a method of implementing an arbitrary concentration-dependent absorbance spectrum of each single-color dye in the visible region through a mathematical model based on absorbance (A) data converted from reflectance (% R or R) data according to one embodiment of the present invention.

In this embodiment, quantitative analysis (generation of calibration curves) is conducted on the concentration-dependent absorbance (A) data of each single-color dye to determine concentration-dependent changes in absorbance of each single-color dye as a function of wavelength in the wavelength range of 360 nm to 700 nm (that is, a wavelength range in CCM colorimetry).

In addition, in this embodiment, functions (for example, fₓ, f_{y}, f_{z}) predicting absorbance as a function of wavelength depending on single-color dyes, a wavelength range, and dye concentrations set by a worker at the dyeing site are combined by regression analysis to generate a mathematical model for each single-color dye, which, in turn, is used to implement absorbance spectra corresponding to the arbitrary concentration of the single-color dyes (that is, concentration-dependent absorbance spectra of the single-color dyes).

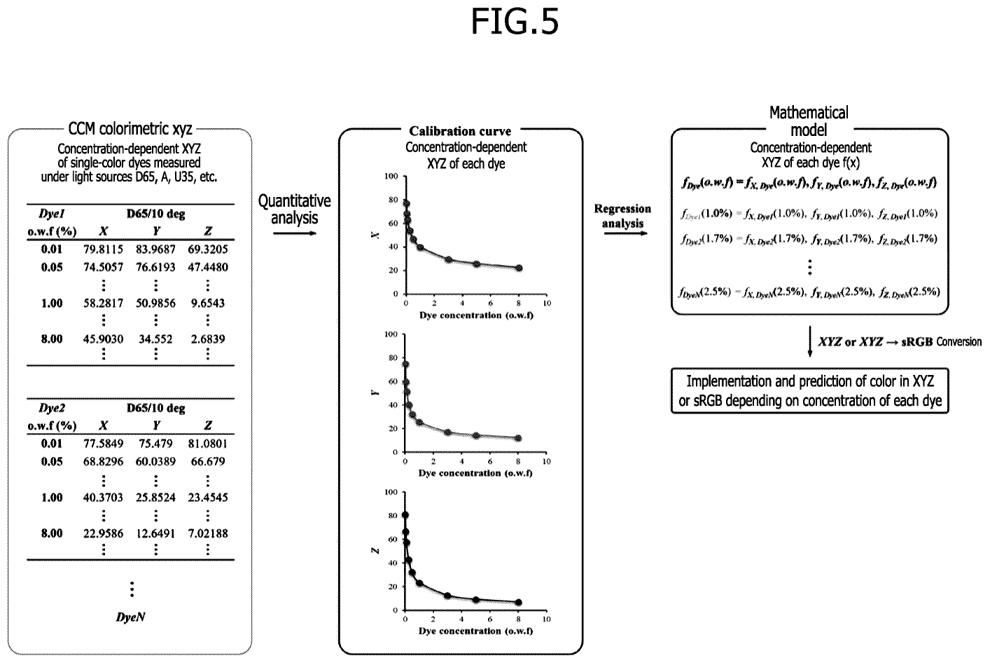

FIG. 5 is a diagram illustrating a method of predicting a color depending on the concentration of a single-color dye according to one embodiment of the present invention.

Using color coordinate X, Y, and Z values in QTX files corresponding to CCM colorimetry results, as measured under a standard light source (for example, D65, A, U35, etc.) set by a worker, change in each of the color coordinate X ,Y, and Z values depending on change in concentration of each single-color dye is determined by quantitative analysis (generation of calibration curves) and, by regression analysis thereon, functions fx, fy, and fz capable of predicting the color coordinate X, Y, and Z values depending on the arbitrary concentration of each single-color dye are combined to generate a mathematical model capable of predicting a color of a dyeing product corresponding to the standard light source and dye concentrations set by the worker at the dyeing site.

The color coordinate X, Y, and Z values calculated through the mathematical model are converted into sRGB values through a specific matrix to display a corresponding color on a monitor.

In addition, the color prediction method according to this embodiment can convert the color coordinate X, Y, and Z values in the QTX file into numerical color values, such as sRGB, HSV, CMYK, and Lab color values, and enables color implementation through quantitative analysis and regression analysis depending on change in concentration of single-color dyes.

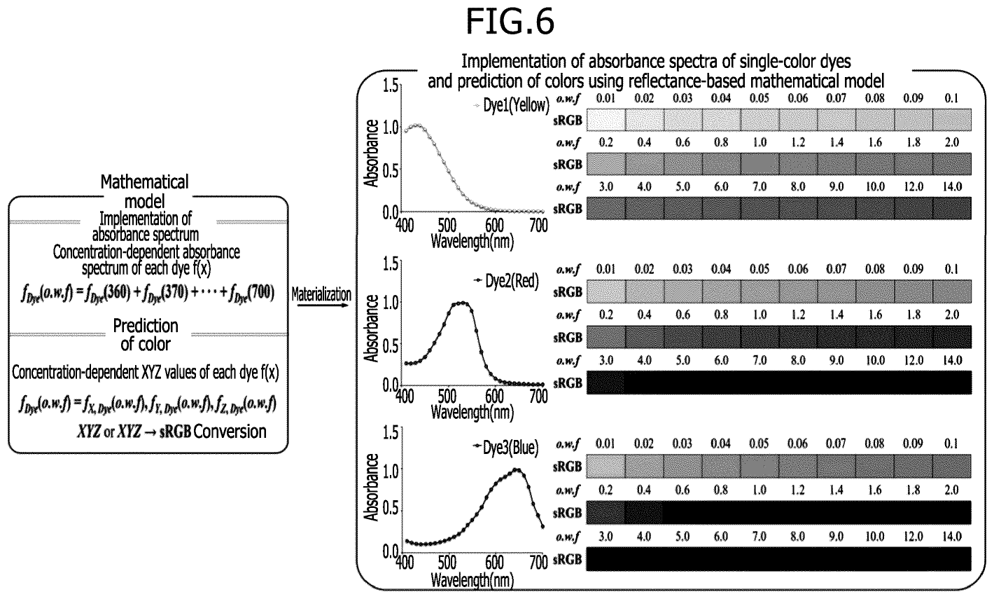

FIG. 6 is a diagram illustrating implementation of absorbance spectra of single-color dyes based on CCM reflectance data and color prediction based thereon shown in FIG. 4 and FIG. 5.

When a worker at the dyeing site sets an arbitrary concentration, through a mathematical model capable of implementing a corresponding absorbance spectrum and a mathematical model capable of predicting a corresponding color, arbitrary concentration-dependent absorbance spectra of single-color dyes selected by the worker are implemented and corresponding predicted colors are output for visual confirmation.

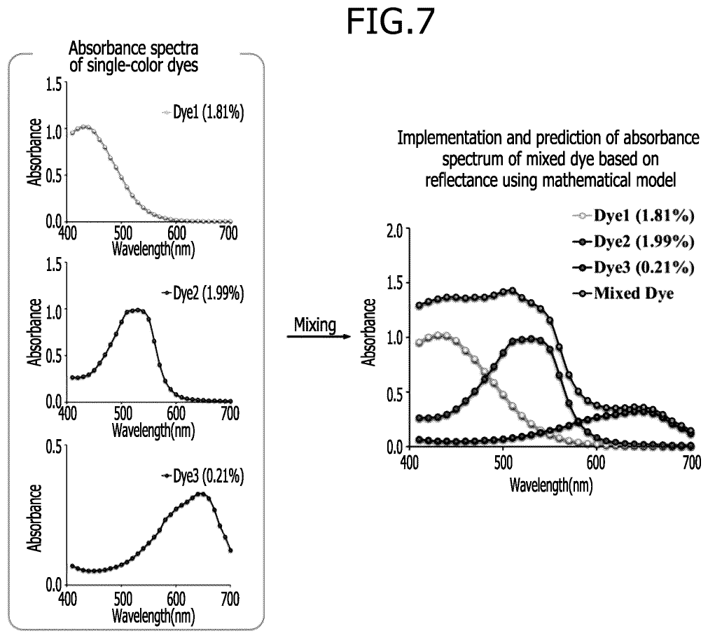

FIG. 7 is a diagram illustrating implementation of absorbance spectra of single-color dyes based on CCM reflectance data and a visible absorbance spectrum of a mixed dye produced according to a specific single-color dye mixing ratio.

Using basic absorbance data of single-color dyes stored at the dyeing site for use in actual production, as calculated through a mathematical model, arbitrary concentration-dependent absorbance spectra of single-color dyes of various colors may be implemented and an absorbance spectrum of a mixed dye produced by mixing the single-color dyes (adding or removing some of the single-color dyes) can be predicted.

The absorbance spectrum of the mixed dye may be output as two absorbance (A) spectra of the mixed dye through the two mathematical formulas described in FIG. 3 (that is, two mathematical formulas for converting reflectance data (% R or R) into absorbance (A) data) and may be compared with two absorbance (A) spectra converted from reflectance data of the customer order to complement or correct the single-color dye mixing ratio.

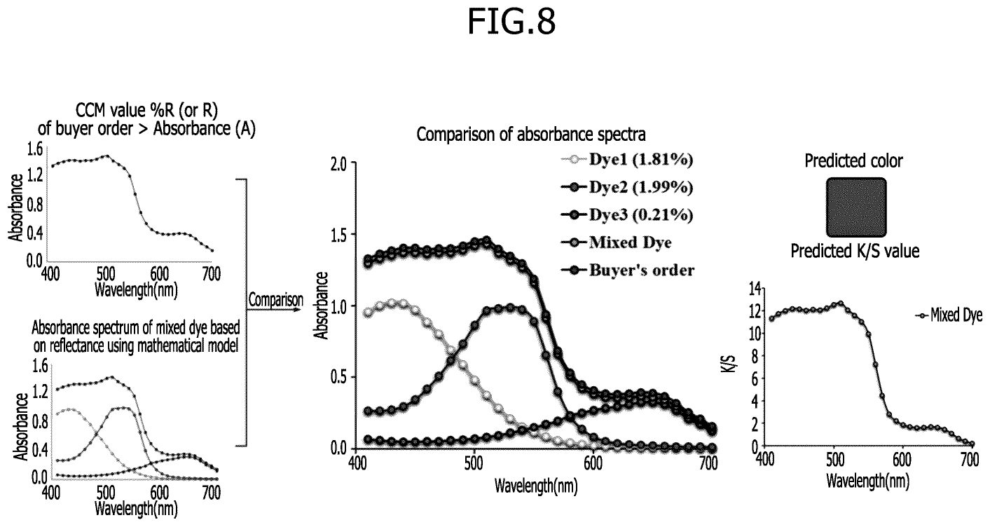

FIG. 8 is a diagram illustrating a method of comparing an absorbance spectrum converted from CCM reflectance data of a customer order with an absorbance spectrum of a mixed dye based on reflectance data generated at the dyeing site.

It is assumed that a QTX file, a color chip, or a swatch sample received from a customer is subjected to colorimetry using a CCM colorimeter at the dyeing site to obtain a QTX file. The contents of this QTX file include a requested color under a light source requested by the customer and on a fabric requested by the customer.

As described above, reflectance data in the QTX file may be converted into absorbance (A) data using a mathematical formula (that is, a formula containing a correction factor). Here, the absorbance (A) data is a value converted based on customer requests.

A recommended single-color dye mixing ratio may be obtained from a CCM system at the dyeing site.

Based on reflectance data-based basic absorbance data of single-color dyes stored and used at the dyeing site, as calculated using a mathematical model, a predicted visible absorbance spectrum of a mixed dye produced according to the recommended single-color dye mixing ratio from the CCM system is output for visual confirmation.

Then, the predicted absorbance (A) spectrum of the mixed dye is compared with the absorbance spectrum converted from the reflectance data of the customer order, the single-color dye mixing ratio recommended by the CCM system is complemented or corrected through adjustment of the concentration of each single-color dye or through replacement with another single-color dye having a similar color to increase matching between the two absorbance spectra, and a predicted color and a predicted color intensity (K/S) based thereon is output for visual confirmation.

In this way, reliance on the know-how of skilled workers for this task can be further reduced, making it possible for workers with relatively little experience in the task to easily cope with the task, and a color difference from the color requested by a customer can be further reduced in a dyeing process including a beaker test (B/T) (a first stage), experimental dyeing (a second stage), and on-site dyeing (a third stage), thereby reducing trial and error in a conventional dyeing process requiring repeated runs and thus reducing the time, labor, and cost associated therewith.

Although some embodiments have been described herein, it should be understood that these embodiments are provided for illustration only and are not to be construed in any way as limiting the present invention, and that various modifications, changes, alterations, and equivalent embodiments can be made by those skilled in the art without departing from the spirit and scope of the invention. The scope of the present invention should be defined by the appended claims and equivalents thereof. The embodiments described herein may be implemented, for example, as a method or process, a device, a software program, a data stream, or a signal. Although discussed in the context of a single type of implementation (for example, discussed only as a method), features discussed herein may also be implemented in other forms (for example, a device or a program). The device may be implemented by suitable hardware, software, firmware, and the like. The method may be implemented on a device, such as a processor that generally refers to a processing device including a computer, a microprocessor, an integrated circuit, a programmable logic device, etc.

What is claimed is:

1. An apparatus for predicting an absorbance spectrum of a mixed dye based on CCM reflectance data, comprising:
an input module receiving input of a customer order for dyeing; and
a processor reproducing an absorbance spectrum through conversion of reflectance data in a QTX file of the customer order,
wherein the processor generates absorbance spectra and predicted colors through conversion of reflectance data of single-color dyes in a dyeing factory; implements a predicted absorbance spectrum of a mixed dye produced according to a recommended single-color dye mixing ratio corresponding to CCM values of the customer order; compares the predicted absorbance spectrum of the mixed dye with the absorbance spectrum according to the customer order; and complements or corrects the recommended single-color dye mixing ratio to match the predicted absorbance spectrum of the mixed dye to the absorbance spectrum according to the customer order.

2. The apparatus according to claim 1, wherein the processor identifies X, Y, and Z values in the QTX file of the customer order using a CCM system; selects single-color dyes stored in the dyeing factory for use in actual production; and outputs the recommended single-color dye mixing ratio by calculating a deviation of X, Y, and Z values of basic data from the identified X, Y, and Z values and performing simulation.

3. The apparatus according to claim 1, wherein the processor converts reflectance (% R or R) data to absorbance (A) data using a mathematical formula containing correction factors A=−log(R) and A=1/log(% R)+α.

4. The apparatus according to claim 1, wherein the processor collects absorbance data converted from reflectance data to construct reflectance-based absorbance data of the single-color dyes used in the dyeing factory.

5. The apparatus according to claim 1, wherein the processor performs regression analysis to generate a mathematical model for each single-color dye through combination of functions predicting absorbance as a function of wavelength depending on single-color dyes, a wavelength range, and dye concentrations set by a worker in the dyeing factory and implements concentration-dependent absorbance spectra of the single-color dyes through the mathematical model.

6. The apparatus according to claim 5, wherein the processor performs quantitative analysis to identify change in color coordinate X, Y, and Z values in a QTX file corresponding to CCM colorimetry results, as measured under a standard light source set by the worker, depending on change in concentration of each single-color dye and combines functions fₓ, f_{y}, and f_{z} capable of predicting the color coordinate X, Y, and Z values depending on an arbitrary concentration of each single-color dye through regression analysis of quantitative analysis results to generate a mathematical model capable of predicting a color of a dyeing product corresponding to the standard light source and the concentration of the single-color dyes set by the worker in the dyeing factory.

7. The apparatus according to claim 1, wherein the processor implements concentration-dependent absorbance spectra of single-color dyes of various colors using basic absorbance data of single-color dyes stored in the dyeing factory for use in actual production, as calculated using a mathematical model, and predicts the absorbance spectrum of the mixed dye produced by mixing the single-color dyes.

8. The apparatus according to claim 1, wherein the processor compares the predicted absorbance spectrum of the mixed dye with the absorbance spectrum converted from the reflectance data of the customer order, complements or corrects a single-color dye mixing ratio recommended by a CCM system through adjustment of the concentration of each single-color dye or through replacement with another single-color dye having a similar color to increase matching between the predicted absorbance spectrum of the mixed dye and the absorbance spectrum converted from the reflectance data of the customer order, and outputs a predicted color and a predicted color intensity (K/S) corresponding to the complemented or corrected single-color dye mixing ratio.

9. A method of predicting an absorbance spectrum of a mixed dye based on CCM reflectance data, comprising:
reproducing, by a processor, an absorbance spectrum through conversion of reflectance data in a QTX file of a customer order;
implementing, by the processor, absorbance spectra and predicted colors through conversion of reflectance data of single-color dyes in a dyeing factory;
generating, by the processor, a predicted absorbance spectrum of a mixed dye produced according to a recommended single-color dye mixing ratio corresponding to CCM values of the customer order;
comparing, by the processor, the predicted absorbance spectrum of the mixed dye with the absorbance spectrum converted from the reflectance data of customer order; and
complementing or correcting, by the processor, the recommended single-color dye mixing ratio to match the predicted absorbance spectrum of the mixed dye to the absorbance spectrum converted from the reflectance data of the customer order.

10. The method according to claim 9, wherein, in order to recommend the single-color dye mixing ratio, the processor identifies X, Y, and Z values in the QTX file of the customer order using a CCM system, selects single-color dyes stored at the dyeing factory for use in actual production, and outputs the recommended single-color dye mixing ratio by calculating a deviation of X, Y, and Z values of basic data from the identified X, Y, and Z values and performing simulation.

11. The method according to claim 9, wherein, in the step of reproducing an absorbance spectrum through conversion of reflectance data in a QTX file of a customer order, the processor converts reflectance (% R or R) data into absorbance (A) data using a mathematical formula containing correction factors A=−log(R) and A=1/log(% R)+α.

12. The method according to claim 9, wherein, the processor performs regression analysis to generate a mathematical model for each single-color dye through combination of functions predicting absorbance as a function of wavelength depending on single-color dyes, a wavelength range, and dye concentrations set by a worker in the dyeing factory and implements concentration-dependent absorbance spectra of the single-color dyes through the mathematical model.

13. The method according to claim 12, wherein, in order to generate the mathematical model for each single-color dye, the processor performs quantitative analysis to identify change in color coordinate X, Y, and Z values in a QTX file corresponding to CCM colorimetry results, as measured under a standard light source set by the worker, depending on change in concentration of each single-color dye, combines functions fₓ, f_{y}, and f_{z} capable of predicting the color coordinate X, Y, and Z values depending on an arbitrary concentration of each single-color dye through regression analysis of quantitative analysis results, and generates a mathematical model capable of predicting a color of a dyeing product corresponding to the standard light source and the concentration of the single-color dyes set by the worker in the dyeing factory.

14. The method according to claim 9, wherein, in the step of generating a predicted absorbance spectrum of a mixed dye, the processor implements concentration-dependent absorbance spectra of single-color dyes of various colors using basic absorbance data of single-color dyes stored in the dyeing factory for use in actual production, as calculated using a mathematical model, and predicts the absorbance spectrum of the mixed dye produced by mixing the single-color dyes.

15. The method according to claim 9, wherein, after generating the predicted absorbance spectrum of the mixed dye and the absorbance spectrum converted from the reflectance data of the customer order, the processor compares the predicted absorbance spectrum of the mixed dye with the absorbance spectrum converted from the reflectance data of the customer order, complements or corrects a single-color dye mixing ratio recommended by a CCM system through adjustment of the concentration of each single-color dye or through replacement with another single-color dye having a similar color to increase matching between the predicted absorbance spectrum of the mixed dye and the absorbance spectrum converted from the reflectance data of the customer order, and outputs a predicted color and a predicted color intensity (K/S) corresponding to the complemented or corrected single-color dye mixing ratio.

16. A method of predicting an absorbance spectrum of a mixed dye based on CCM reflectance data, comprising:
converting, by a processor, reflectance data in a QTX file of a customer order into absorbance data and reproducing an absorbance spectrum based on the absorbance data;
converting, by the processor, reflectance data of single-color dyes in a dyeing factory into absorbance data and generating absorbance spectra of the single-color dyes based on the absorbance data using a specified mathematical model;
generating, by the processor, a predicted absorbance spectrum of a mixed dye produced according to a recommended single-color dye mixing ratio corresponding to CCM values of the customer order based on the absorbance spectra of the single-color dyes; and
comparing, by the processor, the absorbance spectrum converted from the reflectance data of the customer order with the predicted absorbance spectrum of the mixed dye and complementing or correcting the recommended single-color dye mixing ratio to match the predicted absorbance spectrum of the mixed dye to the absorbance spectrum converted from the reflectance data of the customer order.

17. The method according to claim 16, wherein the processor performs regression analysis to generate a mathematical model for each single-color dye through combination of functions predicting absorbance as a function of wavelength depending on single-color dyes, a wavelength range, and dye concentrations set by a worker in the dyeing factory and implements concentration-dependent absorbance spectra of the single-color dyes through the mathematical model.

18. The method according to claim 17, wherein, in order to generate the mathematical model for each single-color dye, the processor performs quantitative analysis to identify change in color coordinate X, Y, and Z values in a QTX file corresponding to CCM colorimetry results, as measured under a standard light source set by the worker, depending on change in concentration of each single-color dye, combines functions fₓ, f_{y}, and f_{z} capable of predicting the color coordinate X, Y, and Z values depending on an arbitrary concentration of each single-color dye through regression analysis of quantitative analysis results, and generates a mathematical model capable of predicting a color of a dyeing product corresponding to the standard light source and the concentration of the single-color dyes set by the worker in the dyeing factory.

19. The method according to claim 16, wherein, in the step of generating a predicted absorbance spectrum of a mixed dye, the processor implements concentration-dependent absorbance spectra of single-color dyes of various colors using basic absorbance data of single-color dyes stored in the dyeing factory for use in actual production, as calculated using a mathematical model, and predicts the absorbance spectrum of the mixed dye produced by mixing the single-color dyes.

20. The method according to claim 16, wherein, after generating the predicted absorbance spectrum of the mixed dye and the absorbance spectrum converted from the reflectance data of the customer order, the processor compares the predicted absorbance spectrum of the mixed dye with the absorbance spectrum converted from the reflectance data of the customer order, complements or corrects a single-color dye mixing ratio recommended by a CCM system through adjustment of the concentration of each single-color dye or through replacement with another single-color dye having a similar color to increase matching between the predicted absorbance spectrum of the mixed dye and the absorbance spectrum converted from the reflectance data of the customer order, and outputs a predicted color and a predicted color intensity (K/S) corresponding to the complemented or corrected single-color dye mixing ratio.
